(19) United States
(12) Patent Application Publication
(10) Pub. No.: US 2008/0093725 A1
(43) Pub. Date: Apr. 24, 2008

(54) SEMICONDUCTOR PACKAGE PREVENTING WARPING AND WIRE SEVERING DEFECTS, AND METHOD OF MANUFACTURING THE SEMICONDUCTOR PACKAGE

(75) Inventors: So-Young JUNG, Daejeon (KR); Se-Young YANG, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/874,826

(22) Filed: Oct. 18, 2007

(30) Foreign Application Priority Data
Oct. 18, 2006 (KR) 10-2006-0101561

(51) Int. Cl. H01L 23/488; H01L 21/58

(52) U.S. Cl. 257/686; 438/109; 257/E23.023; 257/E21.505

(57) ABSTRACT

Provided are a semiconductor package and a method of manufacturing the same. The semiconductor package includes a circuit substrate having a slit inside the circuit substrate, a semiconductor chip formed on an upper surface of the circuit substrate, a wire connecting the semiconductor chip and the circuit substrate through the slit, and a sealant partially covering the wire. According to the semiconductor package, by forming the sealant covering only a part of the wire, wire severing and warping of the semiconductor package can be prevented. In addition, the thickness of a stacked type semiconductor package can be reduced.

### CROSS-REFERENCE TO RELATED PATENT APPLICATION

This application claims priority under 35 USC § 119 to Korean Patent Application No. 10-2006-0101561, filed on Oct. 18, 2006 in the Korean Intellectual Property Office, the disclosure of which is incorporated herein in its entirety by reference.

### BACKGROUND

1. Technical Field

The present invention relates to a semiconductor package and a method of manufacturing the semiconductor package. Specifically, the present invention relates to a wire ball grid array (WBGA) semiconductor package in which a slit is formed in a circuit substrate that is used as a main element of the WBGA semiconductor package, and a method of manufacturing the WBGA semiconductor package.

2. Description of the Related Art

Conventionally, a method of manufacturing a wire ball grid array (WBGA) semiconductor package includes: a wafer sawing operation in which a semiconductor wafer is cut into unit semiconductor chips; a die attaching operation in which the unit cut semiconductor chips are attached on a circuit substrate that is used as a main element of the WBGA semiconductor package together with a lead frame, and a printed circuit substrate (PCB) or a tape wiring board; a wire bonding operation in which the semiconductor chip and the circuit substrate are electrically connected by a wire; an encapsulation operation in which the semiconductor chip, the wire, and a part of the circuit substrate are covered with a sealant; and a solder ball attaching operation in which solder balls are attached on solder ball pads formed under the circuit substrate.

FIG. 1 is a cross-sectional view of a conventional WBGA semiconductor chip package.

Referring to FIG. 1, the conventional WBGA semiconductor package 101 includes a circuit substrate 28 as a main element. A semiconductor chip 36 is formed on the circuit substrate 28. A slit is formed in a middle part of the circuit substrate 28. The circuit substrate 28 includes an upper substrate member 26, a lower substrate member 20 and a substrate wire 22. The semiconductor chip 36 is formed on the circuit substrate 28 using an adhesive member 32. In the conventional WBGA semiconductor package 101, a circuit surface of the semiconductor chip 36, on which a pad 34 is formed, faces the circuit substrate 28. A wire 30 is formed on the circuit substrate 28 to electrically connect the pad 34 on the circuit surface of the semiconductor chip 36 and the substrate wire 22 through the slit. Also, the circuit surface of the semiconductor chip 36 exposed by the slit and the wire 30 are completely sealed by a sealant 24. Solder balls 10 are attached to a lower surface of the circuit substrate 28, which may be connected to an external circuit.

In order to protect the semiconductor chip 36 from external impact and improve the reliability of a semiconductor package 101, a lid 40 may be formed on the semiconductor chip 36 and solder balls 10 are formed between the lid 40 and the circuit substrate 28.

However, a sealant having a low modulus is used in the conventional WBGA semiconductor package due to the fact that when using a sealant having a high modulus, warping of the semiconductor package may occur due to a coefficient of thermal expansion (CTE) difference between the different materials included in the semiconductor package. However, even when using a sealant having a low modulus in the conventional WBGA semiconductor package, wire severing may occur due to thermal expansion caused by environmental conditions such as a high temperature or the like. The present invention addresses these and other disadvantages of the conventional art.

### SUMMARY

The present invention provides a semiconductor package that prevents warping of the semiconductor package and wire severing by improving a structure of the semiconductor package and altering the coverage of a sealant.

The present invention also provides a method of manufacturing the semiconductor package that prevents warping of the semiconductor package and wire severing by improving a structure of the semiconductor package and altering the coverage of the sealant.

According to an aspect of the present invention, there is provided a semiconductor package comprising: a circuit substrate having a slit inside the circuit substrate; a semiconductor chip formed on an upper surface of the circuit substrate; a wire connecting the semiconductor chip and the circuit substrate through the slit; and a sealant partially covering the wire.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a conventional semiconductor chip package;

FIG. 2 is a cross-sectional view illustrating a semiconductor package according to an embodiment of the present invention;

FIG. 3 is a cross-sectional view illustrating a semiconductor package according to another embodiment of the present invention;

FIG. 4 is a cross-sectional view illustrating a semiconductor package according to yet another embodiment of the present invention;

FIG. 5 is a cross-sectional view illustrating a semiconductor package according to still another embodiment of the present invention; and

FIGS. 6A through 6C are cross-sectional views illustrating a method of manufacturing a semiconductor package, according to some embodiments of the present invention.

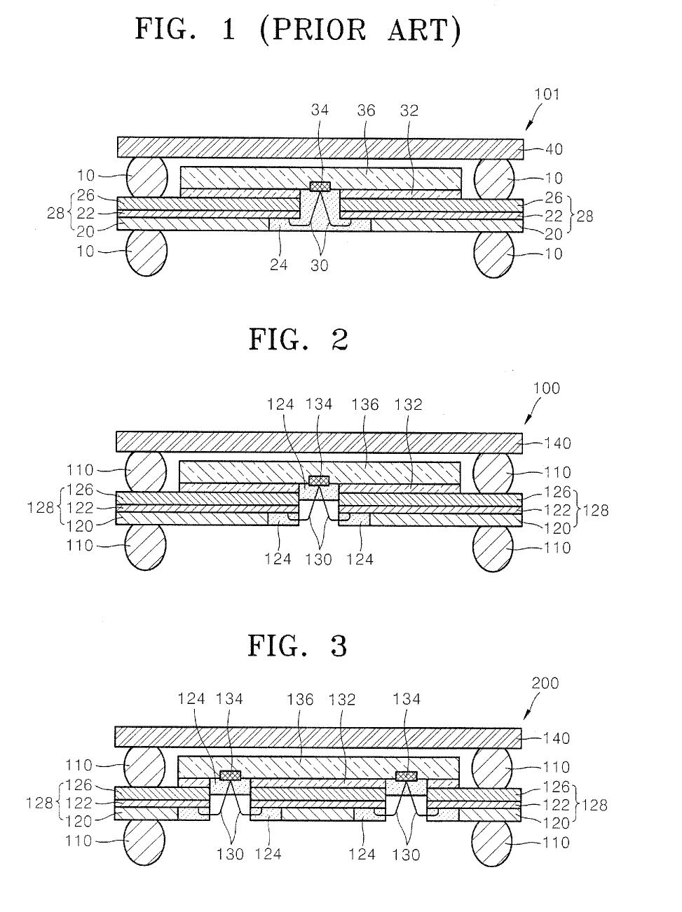

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to one skilled in the art.

FIG. 2 is a cross-sectional view illustrating a semiconductor package 100 according to an embodiment of the present invention.

Referring to FIG. 2, the semiconductor package 100 may include a circuit substrate 128 as a main element. The circuit substrate 128 includes an upper substrate member 126, a lower substrate member 120, and a substrate wire 122. A circuit surface of a semiconductor chip 136 may be attached to the circuit substrate 128 using an adhesive 132, and a slit is formed in a middle part of the circuit substrate 128 so that a circuit surface of the semiconductor chip 136, to which a pad 134 is attached, may face the circuit substrate 128. A wire 130 electrically connects the pad 134 on the circuit surface of the semiconductor chip 136 to the substrate wire 122 through the slit in the middle part of the circuit substrate 128.

A sealant 124 seals the semiconductor package 100 so that only the circuit surface of the semiconductor chip 136, which is exposed by the slit, and a part of the wire 130 may be sealed. In other words, unlike the conventional package, in the semiconductor package 100 of the present invention, a portion of the wire 130 may be exposed outside of the sealant 124. Solder balls 110 are attached to a lower surface of the circuit substrate 128. A lid 140 may be formed on an upper part of the semiconductor chip 136 to protect the semiconductor chip 136 and improve the reliability of the semiconductor package 100.

The semiconductor package 100 is formed so that the sealant 124, having a high modulus in the range of 1.3 to 10 MPa, may cover only a ball bond, which is a connecting portion of the wire 130 and the semiconductor chip 136, and a stitch bond, which is a connecting portion of the wire 130 and the substrate wire 122. Since the wire 130 is only partially covered by the sealant 124, the stress on the wire 130 generated by a coefficient of thermal expansion (CTE) difference between the wire 130 and the sealant 124 is reduced. Simultaneously, the sealant 124, which is formed to partially cover the wire 130 while having a high modulus, prevents a defect such as warping of the semiconductor package 100. Accordingly, severing of the wire 130, which is caused by thermal expansion occurring when a material having a modulus less than 1.3 MPa is used as the sealant 124, can be prevented. In addition, the warping of the semiconductor package 100, which is caused by a stress occurring when a material having a modulus greater than about 1.3 MPa is used as the sealant 124, can be prevented.

When the sealant 124 covers the ball bond, the sealant 124 may partially cover the wire 130 to a thickness in the range of about 5 to about 50 μm, which is effective to prevent the wire from severing. The sealant 124 may cover the stitch bond to a thickness so that the sealant 124 may completely cover the stitch bond.

Since the sealant 124 partially covers a part of the wire 130, the wire 130 may be coated with an antioxidant which prevents oxidation of the exposed part of the wire 130.

Also, it is understood by one of ordinary skill in the art that the circuit surface of the semiconductor chip 136 may face the lid 140. In this case, a through via is formed in the semiconductor chip 136 and then the pad 134 may be formed corresponding to the semiconductor chip 136 of FIG. 2. Then, the pad 134 is connected to the circuit substrate 128 through the wire 130.

FIG. 3 is a cross-sectional view illustrating a semiconductor package 200 according to another embodiment of the present invention.

Referring to FIG. 3, the semiconductor package 200 may include a circuit substrate 128 as a main element. The circuit substrate 128 includes an upper substrate member 126, a lower substrate member 120 and a substrate wire 122. A semiconductor chip 136 may be formed on an upper part of the circuit substrate 128, and slits are formed in side parts of the circuit substrate 128. In comparing FIG. 2 with FIG. 3, the positions of the slits are different.

The semiconductor package 200 includes a semiconductor chip 136, wires 130, a sealant 124 and solder balls 110. The semiconductor chip 136 is attached to the circuit substrate 128 using an adhesive member 132 so that a circuit surface of the semiconductor chip 136, to which pads 134 are attached, may face the circuit substrate 128. The wires 130 electrically connect the pads 134 on the circuit surface of the semiconductor chip 136 to the substrate wire 122 through the slits of the circuit substrate 128. The sealant 124 covers only the circuit surface of the semiconductor chip 136 exposed by the slits and a part of the wires 130, for example, only a ball bond and a stitch bond. The solder balls 110 are attached to a lower surface of the circuit substrate 128.

A lid 140 may be formed on an upper part of the semiconductor chip 136 to protect the semiconductor chip 136 and improve the reliability of the semiconductor package 200. The current embodiment of the present invention is appropriate when, for example, a semiconductor chip having edge pads is applied to a wire ball grid array (WBGA) semiconductor package.

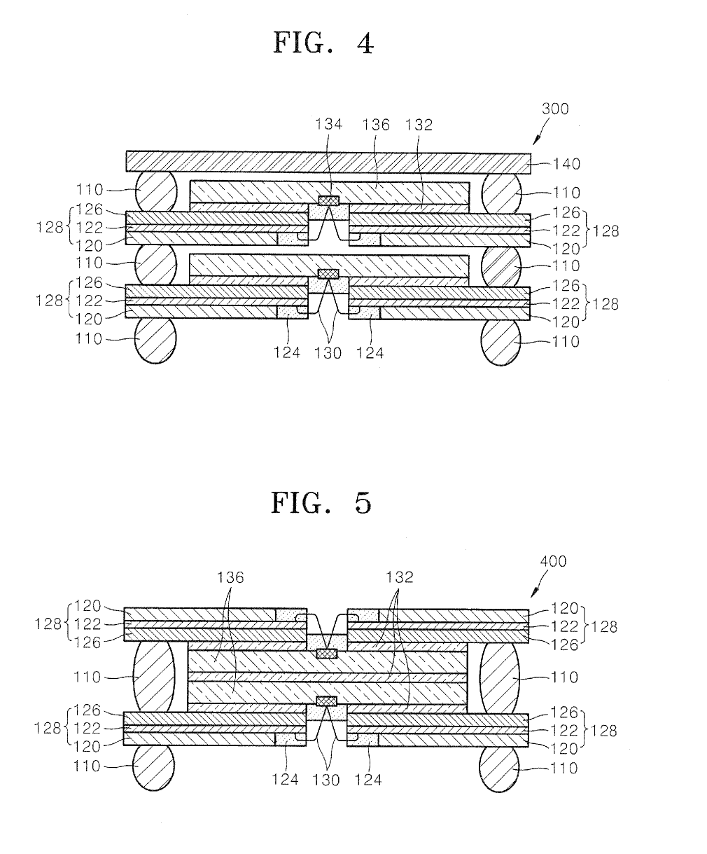

FIG. 4 is a cross-sectional view illustrating a semiconductor package 300 according to yet another embodiment of the present invention.

Referring to FIG. 4, the semiconductor package 300 includes two stacked semiconductor packages, each of which has the same structure as that of the semiconductor package 100 of FIG. 2. In the present embodiment, semiconductor chips 136 included in upper and lower semiconductor packages may be of the same or different part type. The upper and lower semiconductor packages may be electrically connected through the solder balls 110. Also, it is understood by one of ordinary skill in the art that a plurality of semiconductor packages may be stacked.

FIG. 5 is a cross-sectional view illustrating a semiconductor package 400 according to still another embodiment of the present invention.

Referring to FIG. 5, the semiconductor package 400 includes two stacked semiconductor packages. An upper semiconductor package of the two stacked semiconductor packages of the semiconductor package 400 has an inverted structure as compared to the semiconductor package 100 of FIG. 2. A lower semiconductor package of the two stacked semiconductor packages has the same structure as that of the semiconductor package 100 of FIG. 2 except that the lid 140 is omitted. Semiconductor chips 136 of the upper and lower semiconductor packages are attached to each other using an adhesive member 132. Since there is no space between the semiconductor chips 136 of the upper and lower semiconductor packages, the thicknesses of two stacked semiconductor packages can be reduced.

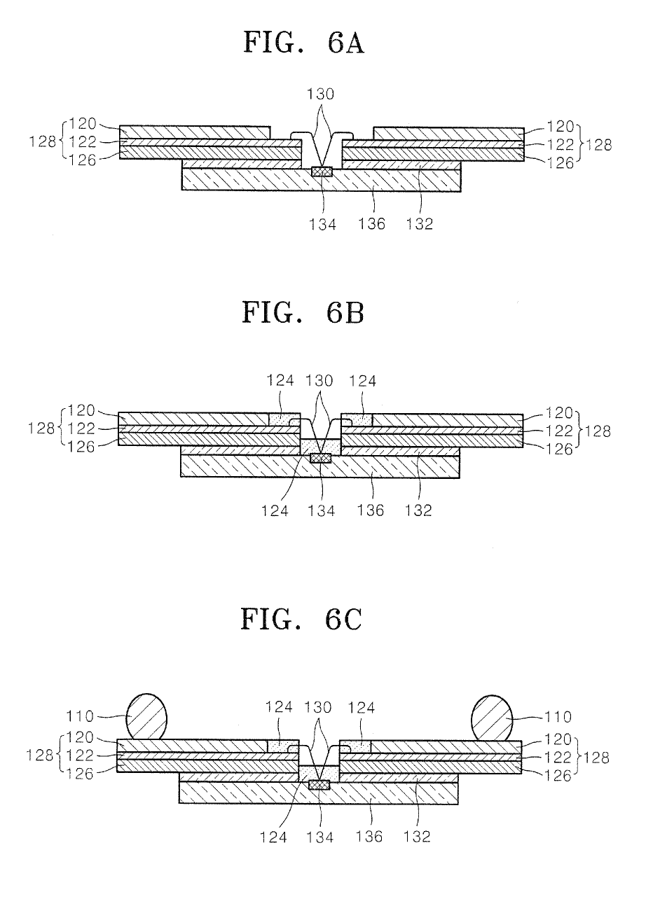

FIGS. 6A through 6C are cross-sectional views illustrating a method of manufacturing a semiconductor package, according to some embodiments of the present invention.

Referring to FIG. 6A, a circuit substrate 128 having a slit in the middle of the circuit substrate 128 is attached to a semiconductor chip 136 using an adhesive member 132. A wire 130 is bonded through the slit in order to electrically connect the semiconductor chip 136 to the circuit substrate 128. The wire 130 is connected to a pad 134 formed on the semiconductor chip 136 and a substrate wire 122 of the circuit substrate 128.

Referring to FIG. 6B, a part of the wire 130 is covered with a sealant 124. The sealant 124 is formed on a ball bond, which is a portion of the wire 130 adhered to the semiconductor chip 136. The sealant 124 is formed on a stitch bond, which is a portion of the wire 130 adhered to the substrate wire 122. Also, the order of the above-mentioned operation may be inverted. When the sealant 124 is formed on the stitch bond, the sealant 124 may have an appropriate viscosity in order to prevent the sealant 124 from melting. If necessary, curing of the sealant 124 may be performed.

Also, it is understood by one of ordinary skill in the art that the sealant 124 may be formed by a method including forming the sealant 124 on the entire slit and selectively etching a middle part of the sealant 124.

Referring to FIG. 6C, solder balls 110 are attached to the lower substrate member 120 of the circuit substrate 128 included in the semiconductor package, in which the sealant 124 is formed, in order to electrically connect the circuit substrate 128 to an external circuit. Alternatively, the solder balls 110 can also be attached to side parts of an upper surface of the circuit substrate 128, and the lid 140 may be formed on the upper part of the circuit substrate 128 as illustrated in FIG. 3. In addition, before attaching the solder balls 110 and the lid 140, the stacked semiconductor package may also be formed as illustrated in FIGS. 4 and 5.

According to some embodiments of the present invention, by forming a sealant only on a part of a wire, wire severing and warping of the semiconductor package can be prevented. In addition, when a stacked type semiconductor package is manufactured, chips of upper and lower packages are attached to each other. Thus, the thickness of the semiconductor package can be reduced.

According to an aspect of the present invention, there is provided a semiconductor package comprising: a circuit substrate having a slit inside the circuit substrate; a semiconductor chip formed on an upper surface of the circuit substrate; a wire connecting the semiconductor chip and the circuit substrate through the slit; and a sealant partially covering the wire.

The part of the wire partially covered with the sealant may be a ball bond which is a connecting portion of the wire and the semiconductor chip.

According to another aspect of the present invention, there is provided a method of manufacturing a semiconductor package, comprising: forming a semiconductor chip on an upper surface of a circuit substrate on which a slit is formed; connecting the semiconductor chip and the circuit substrate through a wire; and sealing only a part of the wire using a sealant.

The sealing only the part of the wire by the sealant may comprise sealing a ball bond which is an adhesive part of the wire and the semiconductor chip by the sealant; and sealing a stitch bond which is an adhesive part of the wire and the circuit substrate by the sealant.

After the attaching of the solder balls on the lower surface of the circuit substrate, the method may further comprise stacking another semiconductor package on the semiconductor package having the same structure as that of the semiconductor package on the circuit substrate.

The stacked semiconductor package may be formed so that the solder balls of the stacked semiconductor package are connected to the upper surface of the circuit substrate of the semiconductor package.

The stacked semiconductor package may be formed so that the stacked semiconductor package is stacked as an inverted structure and each of the semiconductor chips of the stacked semiconductor package and the semiconductor package are connected to each other using an adhesive member.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A semiconductor package comprising:
a circuit substrate having a slit inside the circuit substrate;
a semiconductor chip formed on an upper surface of the circuit substrate;
a wire connecting the semiconductor chip and the circuit substrate through the slit; and
a sealant partially covering the wire, wherein a portion of the wire is exposed outside of the sealant.

2. The semiconductor package of claim 1, wherein the part of the wire partially covered with the sealant is a ball bond which is a connecting portion of the wire and the semiconductor chip.

3. The semiconductor package of claim 1, wherein the part of the wire partially covered with the sealant is a stitch bond which is a connecting portion of the wire and the circuit substrate.

4. The semiconductor package of claim 1, wherein the slit is formed in a middle part of the circuit substrate.

5. The semiconductor package of claim 1, further comprising another slit, wherein the slits are formed in side parts of the circuit substrate.

6. The semiconductor package of claim 1, wherein the wire is coated by an antioxidant.

7. The semiconductor package of claim 1, wherein the semiconductor package further comprises solder balls attached on a lower surface of the circuit substrate.

8. The semiconductor package of claim 7, wherein the semiconductor package further comprises solder balls attached on side parts of an upper surface of the circuit substrate and a lid formed on the solder balls.

9. The semiconductor package of claim 7, wherein the semiconductor package is stacked on the circuit substrate, and further comprises a stacked semiconductor package having the same structure as that of the semiconductor package.

10. The semiconductor package of claim 9, wherein the stacked semiconductor package further comprises solder balls attached on side parts of an upper surface of the circuit substrate and a lid formed on the solder balls.

11. The semiconductor package of claim 1, wherein the sealant has a modulus in the range of about 1.3 to about 10 MPa.

12. A method of manufacturing a semiconductor package, comprising:
forming a semiconductor chip on an upper surface of a circuit substrate on which a slit is formed;
connecting the semiconductor chip and the circuit substrate through a wire; and
sealing only a part of the wire using a sealant.

13. The method of claim 12, wherein sealing only part of the wire using the sealant comprises:
sealing a ball bond which is a connecting part of the wire and the semiconductor chip using the sealant; and
sealing a stitch bond which is a connecting part of the wire and the circuit substrate using the sealant after sealing the ball bond.

14. The method of claim 12, wherein sealing only part of the wire using the sealant comprises:
sealing a stitch bond which is a connecting part of the wire and the circuit substrate using the sealant; and
sealing a ball bond which is a connecting part of the wire and the semiconductor chip using the sealant after sealing the stitch bond.

15. The method of claim 12, further comprising, after sealing the part of the wire, attaching solder balls on a lower surface of the circuit substrate.

16. The method of claim 15, further comprising, after the attaching of the solder balls on the lower surface of the circuit substrate, forming a stacked semiconductor package on the semiconductor package having substantially the same structure as that of the semiconductor package on the circuit substrate.

17. The method of claim 16, wherein after forming the stacked semiconductor package, further comprising:
attaching solder balls on side parts of an upper surface of a circuit substrate of the stacked semiconductor package; and
attaching a lid to the solder balls.

18. The method of claim 16, wherein the solder balls of the stacked semiconductor package are connected to the upper surface of the circuit substrate of the semiconductor package.

19. The method of claim 16, wherein the stacked semiconductor package is stacked as an inverted structure and each of the semiconductor chips of the stacked semiconductor package and the semiconductor package are connected to each other using an adhesive member.

20. The method of claim 12, wherein after sealing the part of the wire, further comprising:
attaching solder balls on side parts of an upper surface of the circuit substrate; and
attaching a lid to the solder balls.
